(19) United States
(12) Patent Application Publication
(10) Pub. No.: US 2026/0231555 A1
(43) Pub. Date: Aug. 6, 2026

(54) METHOD FOR MANUFACTURING DIVIDED SOLAR CELL, AND DIVIDED SOLAR CELL

(71) Applicant: KANEKA CORPORATION, Osaka (JP)

(72) Inventor: Masanori FUKUDA, Osaka-shi, Osaka (JP)

(73) Assignee: KANEKA CORPORATION, Osaka (JP)

(21) Appl. No.: 19/151,270

(22) PCT Filed: Nov. 24, 2023
(86) PCT No.: PCT/JP2023/042150

§ 371 Date: Jul. 25, 2025

(30) Foreign Application Priority Data
Jan. 26, 2023 (JP) 2023-010068

(51) Int. Cl. H10F 71/00; H10F 77/30

(52) U.S. Cl. CPC H10F 71/136; H10F 77/311

(57) ABSTRACT

The present invention provides a method for manufacturing a divided solar cell capable of suppressing influence on a photoelectric conversion substrate when a solar cell is divided as compared with a conventional technique, and a divided solar cell having higher reliability than a conventional technique. The method is configured to include a first electrode forming step of applying conductive paste containing liquid resin onto a first main surface of a photoelectric conversion substrate and solidifying the conductive paste in a state where a part of the liquid resin of the conductive paste oozes out from an applied area on the photoelectric conversion substrate, so as to form a first electrode part and a first resin coating part containing a resin component of the liquid resin, and a dividing groove forming step of forming a dividing groove from a side of the first main surface of the photoelectric conversion substrate on which the first electrode part and the first resin coating part are formed in the first electrode forming step so as to pass through the first resin coating part.

### TECHNICAL FIELD

The present invention relates to a method for manufacturing a divided solar cell and a divided solar cell.

### BACKGROUND ART

In recent years, there has been known a solar cell module in which one panel-shaped solar cell is divided into a plurality of strip-shaped divided solar cells, and end sides of the divided solar cells are electrically connected to each other (for example, Patent Document 1).

In the solar cell module of Patent Document 1, since end sides of the divided solar cells are connected in an overlapping manner (referred to as shingling connection), an effective light receiving area can be increased, and conversion efficiency is considered to be higher than that in a conventional technique.

### PRIOR ART DOCUMENT

### Patent Document

Patent Document 1: WO 2020/158379 A

### DISCLOSURE OF INVENTION

### Technical Problem

In the solar cell module of Patent Document 1, when an in-process solar cell is cut, cutting is performed by irradiating a photoelectric conversion substrate with laser beam to form a groove, and then performing cleaving by using the groove as a starting point.

However, since the solar cell module of Patent Document 1 is obtained by directly irradiating a photoelectric conversion substrate with laser beam, a part of the photoelectric conversion substrate may be damaged or deteriorated by energy of the laser beam, or a cut fragment generated at the time of cutting may adhere to a cut surface, there is a substantial impact on a photoelectric conversion substrate during cutting of a solar cell, and there has been room for further improvement from the viewpoint of reliability.

In view of the above, an object of the present invention is to provide a method for manufacturing a divided solar cell capable of suppressing influence on a photoelectric conversion substrate when the solar cell is divided as compared with a conventional technique, and a divided solar cell having higher reliability than a conventional technique.

### Solution to Problem

One aspect of the present invention for solving the above-described problem is a method for manufacturing a divided solar cell, the method including a first electrode forming step of applying conductive paste containing liquid resin onto a first main surface of a photoelectric conversion substrate and solidifying the conductive paste in a state where a part of the liquid resin of the conductive paste oozes out from an applied area on the photoelectric conversion substrate, so as to form a first electrode part and a first resin coating part containing a resin component of the liquid resin, and a dividing groove forming step of forming a dividing groove from a side of the first main surface of the photoelectric conversion substrate on which the first electrode part and the first resin coating part are formed in the first electrode forming step so as to pass through the first resin coating part.

According to this aspect, since a portion where the dividing groove is formed of the photoelectric conversion substrate is protected by the first resin coating part, it is possible to suppress influence on the photoelectric conversion substrate when the dividing groove is formed.

One aspect of the present invention is a method for manufacturing a divided solar cell, the method including a second electrode forming step of applying conductive paste containing liquid resin onto a second main surface of a photoelectric conversion substrate, and solidifying the conductive paste in a state where a part of the liquid resin of the conductive paste oozes out from an applied area on the photoelectric conversion substrate, so as to form a second electrode part and a second resin coating part containing a resin component of the liquid resin, a dividing groove forming step of forming a dividing groove from a side of a first main surface of the photoelectric conversion substrate on which the second electrode part and the second resin coating part are formed in the second electrode forming step so as to pass through a position overlapping the second resin coating part in plan view, and a breaking apart step of breaking apart the photoelectric conversion substrate on which the dividing groove is formed along the dividing groove from the dividing groove to the second resin coating part to divide the photoelectric conversion substrate into a plurality of divided solar cells.

According to this aspect, since a portion to be broken apart of the photoelectric conversion substrate is protected by the second resin coating part, it is possible to suppress influence on the photoelectric conversion substrate at the time of breaking apart.

In a preferred aspect, the photoelectric conversion substrate on which the dividing groove is formed is broken apart along the dividing groove to be divided into a plurality of divided solar cells.

In a preferred aspect, in the dividing groove forming step, the dividing groove is formed by irradiating with laser beam.

One aspect of the present invention is a divided solar cell including a photoelectric conversion substrate, a first electrode part formed on the photoelectric conversion substrate, and a resin coating part adjacent to the first electrode part, in which the first electrode part and the resin coating part contain a common resin component, the photoelectric conversion substrate has a protective resin layer formed on a part or the whole of an end surface, and the protective resin layer is continuous with the resin coating part and contains the resin component or an oxide component of the resin component.

According to this aspect, since the protective resin layer is formed on a part or the whole of an end surface of the photoelectric conversion substrate, a short circuit at the end surface of the photoelectric conversion substrate hardly occurs, and reliability is high.

### Effect of Invention

According to the method for manufacturing a divided solar cell of the present invention, influence on a photoelectric conversion substrate when a solar cell is divided can be suppressed as compared with a conventional technique.

The divided solar cell of the present invention has higher reliability than a conventional technique.

### BRIEF DESCRIPTION OF DRAWINGS

FIG. 1 is a perspective view of a stacked structure of a solar cell according to a first embodiment of the present invention.

FIG. 2 is a plan view of the solar cell of FIG. 1.

FIG. 3 is an explanatory view of the solar cell of FIG. 1, in which FIG. 3A is a perspective view as viewed from a first cell main surface side, and FIG. 3B is a perspective view as viewed from a second cell main surface side by rotating the solar cell of FIG. 3A in a direction of an arrow R.

FIG. 4 is an explanatory view of the solar cell of FIG. 2, in which FIG. 4A is an end surface view of an A-A cross section of FIG. 2, and FIG. 4B is an end surface view of a B-B cross section of FIG. 2.

FIG. 5 is an explanatory view of the solar cell of FIG. 4, in which FIG. 5A is an enlarged view of a C region of FIG. 4A, and FIG. 5B is an enlarged view of a D region of FIG. 4A.

FIG. 6 is a plan view of a solar cell module using a divided solar cell obtained by dividing the solar cell of FIG. 1, in which a first sealing member and a first sealing material are omitted for easy understanding.

FIG. 7 is an end surface view of a cross section of the solar cell module of FIG. 6, and hatching of the first sealing material and a second sealing material is omitted for easy understanding.

FIG. 8 is a cross-sectional perspective view of the divided solar cell of FIG. 6.

FIG. 9 is an explanatory view of a solar cell manufacturing step for manufacturing the solar cell of FIG. 1, in which FIG. 9A is a cross-sectional view after a photoelectric conversion part forming step, and FIG. 9B is a cross-sectional view after a transparent conductive layer forming step. Note that FIG. 9B illustrates a dot for a portion formed in each step, and hatching is omitted for other portions.

FIG. 10 is an explanatory view of a solar cell manufacturing step for manufacturing the solar cell of FIG. 1, in which FIG. 1A is a cross-sectional view after a first electrode forming step, and FIG. 1B is a cross-sectional view after a second electrode forming step. Note that FIGS. 10A and 10B show a dot for a portion formed in each step, and hatching is omitted for other portions.

FIG. 11 is an explanatory view of a positional relationship between solar cells in a stacked structure forming step of forming the stacked structure of the solar cell in FIG. 1, in which FIG. 11A is an end surface view of a cross section in a longitudinal direction, and FIG. 11B is an end surface view of a cross section in a direction (lateral direction) orthogonal to the cross section in FIG. 11A.

FIG. 12 is an explanatory view of a solar cell processing step of processing the solar cell of FIG. 2, in which FIG. 12A is a cross-sectional view after a laser step and FIG. 12B is a cross-sectional view after a breaking apart step. Note that, in FIGS. 12A and 12B, hatching is omitted for easy understanding.

FIG. 13 is an explanatory view of a main part of the solar cell according to another embodiment of the present invention, in which FIG. 13A is a plan view of an embodiment in which a plurality of second finger electrode parts are located between first finger electrode parts, and FIG. 13B is a plan view of an embodiment in which a plurality of the first finger electrode parts are located between the second finger electrode parts.

FIG. 14 is an explanatory view of a solar cell processing step of processing the solar cell according to another embodiment of the present invention, in which FIG. 14A is a cross-sectional view of the solar cell after a laser step, and FIG. 14B is a cross-sectional view of the solar cell after a breaking apart step. Note that, in FIGS. 14A and 14B, hatching is omitted for easy understanding.

### BEST MODE FOR CARRYING OUT THE INVENTION

Hereinafter, an embodiment of the present invention will be described in detail.

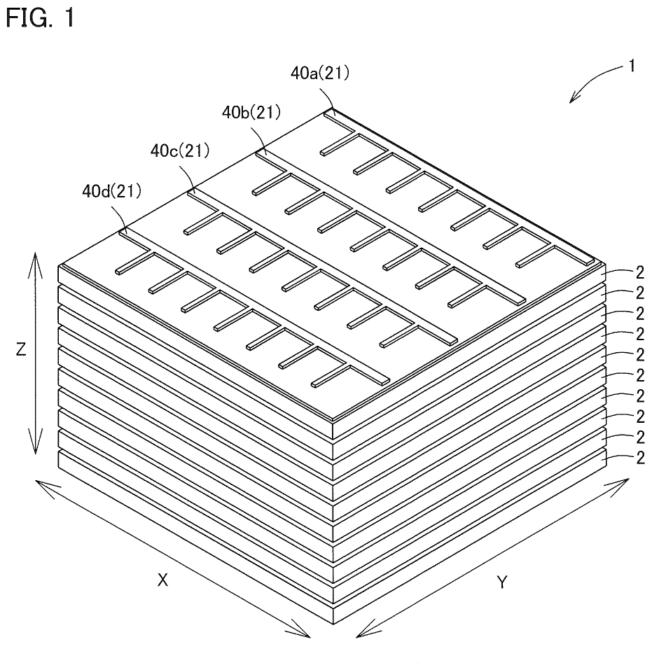

As illustrated in FIG. 1, a stacked structure 1 of solar cells (hereinafter, simply referred to as the stacked structure 1) according to a first embodiment of the present invention is a stacked body having a plurality of solar cells 2 and having the solar cells 2 stacked in a top-bottom direction (vertical direction Z).

That is, in the stacked structure 1, the solar cells 2 are stacked in a laid state, and most of the solar cells 2 on the upper stage side overlap the solar cell 2 on the lower stage side.

In the stacked structure 1 of the present embodiment, 90% or more of the solar cells 2 on the upper stage side overlap the solar cell 2 on the lower stage side in plan view.

Note that the number of the solar cells 2 stacked constituting the stacked structure 1 is not particularly limited.

### Solar Cell 2

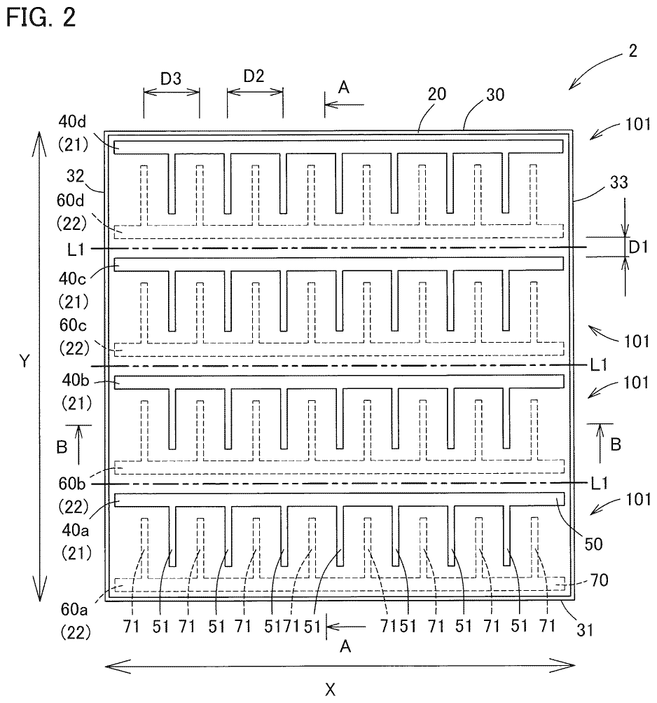

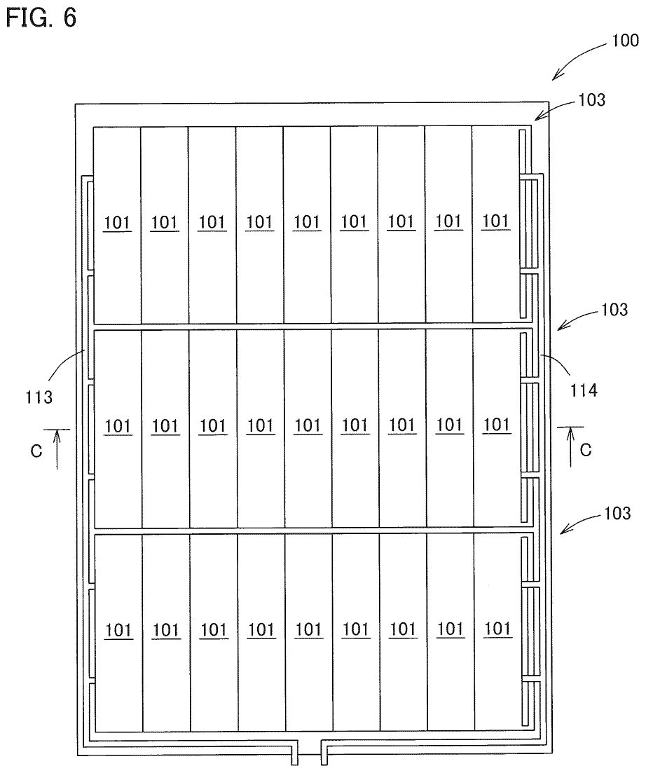

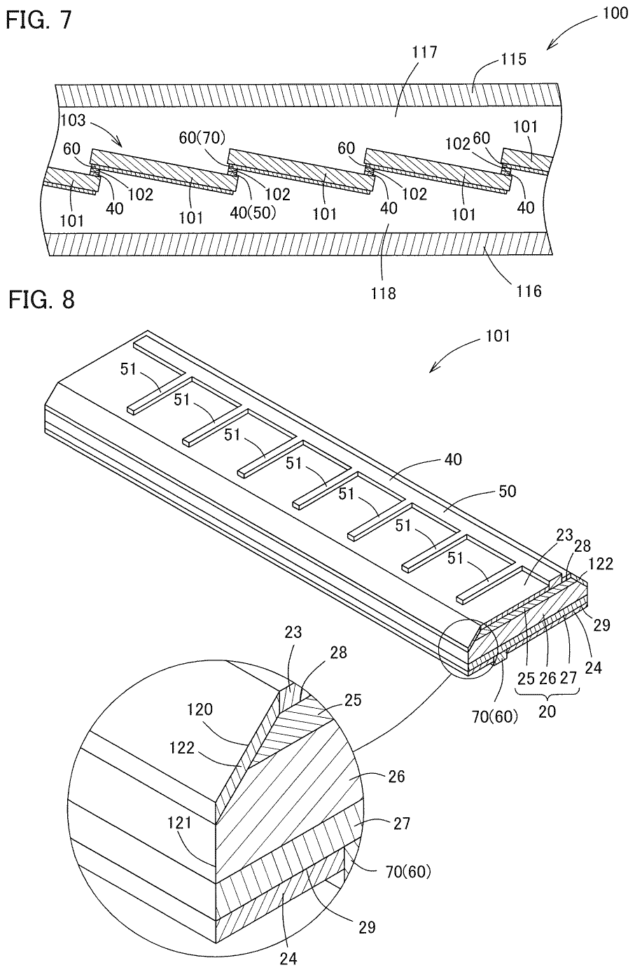

The solar cell 2 is used by being divided into a plurality of divided solar cells 101 having a strip shape by being cut along a division line L1 illustrated in FIG. 2, and forms a solar cell module 100 having a solar cell group 103 in which the divided solar cells 101 are connected directly or via a conductive adhesive 102 as illustrated in FIGS. 6 and 7. That is, the solar cell 2 is an in-process solar cell which is an in-process product of the solar cell module 100.

The solar cell 2 of the present embodiment is a crystalline solar cell, and is a heterojunction solar cell.

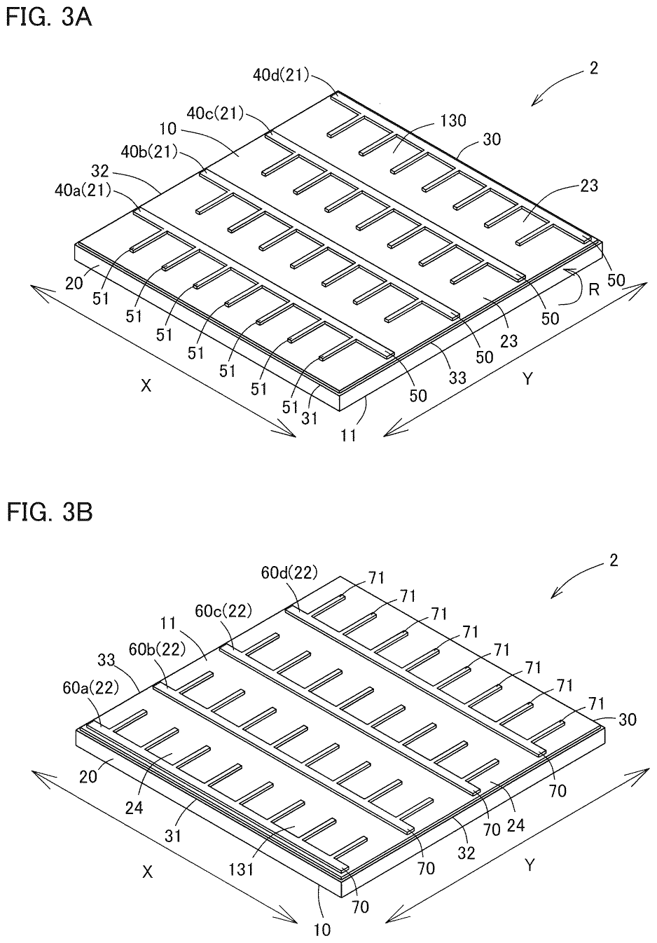

As illustrated in FIG. 3, the solar cell 2 is a plate-shaped cell having both main surfaces, a first cell main surface 10 and a second cell main surface 11, and includes a photoelectric conversion substrate 20, a first electrode part 21, a second electrode part 22, a first resin coating part 23, and a second resin coating part 24.

As illustrated in FIG. 2, the solar cell 2 has a quadrangular shape when the photoelectric conversion substrate 20 is viewed in plan view, and includes lateral sides 30 and 31 extending in a lateral direction X and longitudinal sides 32 and 33 extending in a longitudinal direction Y.

In the solar cell 2, the lateral sides 30 and 31 are parallel to each other, and the longitudinal sides 32 and 33 are parallel to each other.

### Photoelectric Conversion Substrate 20

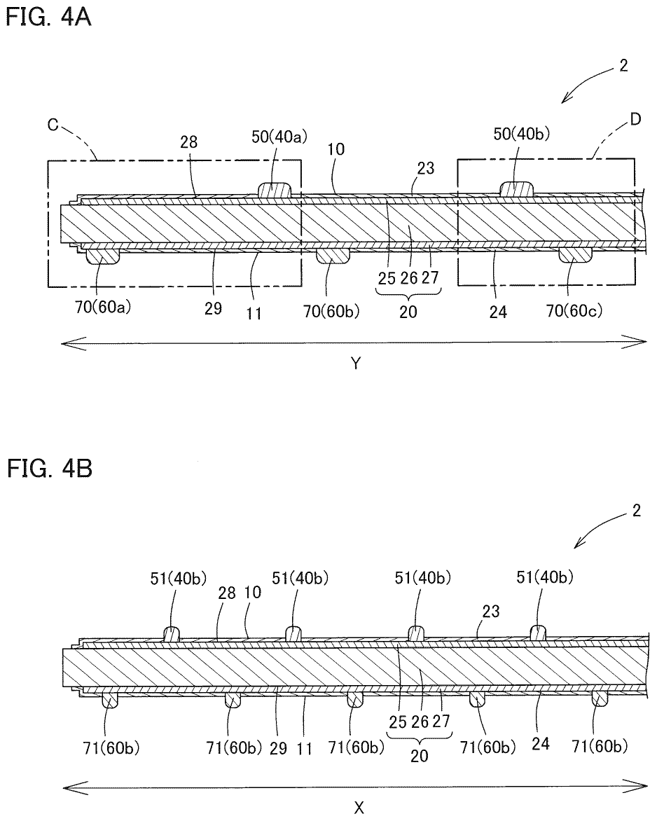

As illustrated in FIG. 4, the photoelectric conversion substrate 20 is a plate-like substrate having both main surfaces, a first substrate main surface 28 (first main surface) and a second substrate main surface 29 (second main surface), and includes a first transparent conductive layer 25, a photoelectric conversion part 26, and a second transparent conductive layer 27. Here, in the photoelectric conversion substrate 20 of the present embodiment, the first substrate main surface 28 (first main surface) is a main light receiving surface.

The transparent conductive layers 25 and 27 are conductive layers that form a pair with each other and take out electricity from the photoelectric conversion part 26, and are underlying conductive layers serving as bases of the electrode parts 21 and 22.

The transparent conductive layers 25 and 27 are not particularly limited as long as they have transparency and conductivity, and are made from, for example, a transparent conductive oxide such as an indium tin oxide (ITO).

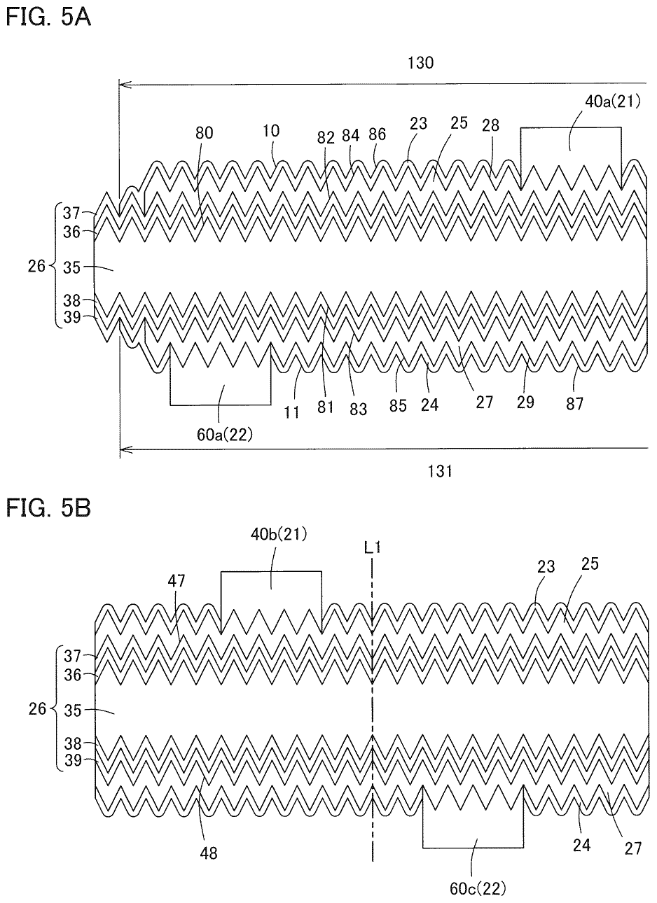

The photoelectric conversion part 26 is a portion that converts light energy into electric energy, and includes a semiconductor substrate 35, a first intrinsic semiconductor layer 36, a first conductivity-type semiconductor layer 37, a second intrinsic semiconductor layer 38, and a second conductivity-type semiconductor layer 39 as illustrated in FIG. 5.

In the photoelectric conversion part 26, the first intrinsic semiconductor layer 36 and the first conductivity-type semiconductor layer 37 are laminated in this order on one main surface side (the first cell main surface 10 side) of the semiconductor substrate 35, and the second intrinsic semiconductor layer 38 and the second conductivity-type semiconductor layer 39 are laminated in this order on another main surface side (the second cell main surface 11 side) of the semiconductor substrate 35.

The semiconductor substrate 35 is a substrate having an n-type or p-type conductivity type such as n-type silicon or p-type silicon.

The semiconductor substrate 35 has a conductivity type opposite to that of the first conductivity-type semiconductor layer 37, and has the same conductivity type as that of the second conductivity-type semiconductor layer 39.

For example, in a case where the semiconductor substrate 35 is made from a p-type semiconductor, the first conductivity-type semiconductor layer 37 is formed of an n-type semiconductor, and the second conductivity-type semiconductor layer 39 is formed of a p-type semiconductor. On the other hand, in a case where the semiconductor substrate 35 is made from an n-type semiconductor, the first conductivity-type semiconductor layer 37 is formed of a p-type semiconductor, and the second conductivity-type semiconductor layer 39 is formed of an n-type semiconductor.

That is, in the photoelectric conversion part 26, a PN junction portion is formed on the first cell main surface 10 side with respect to the semiconductor substrate 35.

The PN junction portion is a portion where a p-type semiconductor and an n-type semiconductor are joined directly or via an intrinsic semiconductor in a thickness direction of the photoelectric conversion part 26, and is formed closer to the first cell main surface 10 than the center in the thickness direction of the photoelectric conversion part 26.

The first intrinsic semiconductor layer 36 is a layer formed of an intrinsic semiconductor such as i-type silicon.

The first conductivity-type semiconductor layer 37 is a semiconductor layer having an n-type or p-type conductivity type such as n-type silicon or p-type silicon.

The second intrinsic semiconductor layer 38 is a layer formed of an intrinsic semiconductor such as i-type silicon.

The second conductivity-type semiconductor layer 39 is a semiconductor layer having a p-type or n-type conductivity type such as p-type silicon or n-type silicon, and has a conductivity type different from that of the first conductivity-type semiconductor layer 37.

As illustrated in FIG. 5, in the photoelectric conversion substrate 20, first texture structures 80 and 81 in which surface irregularities are formed are formed on both one main surface (surface on the first substrate main surface 28 side) and the other main surface (surface on the second substrate main surface 29 side) of the semiconductor substrate 35.

In the photoelectric conversion substrate 20, the semiconductor layers 36 and 37 on one main surface of the semiconductor substrate 35 follow and reflect irregularities of the first texture structure 80 of the semiconductor substrate 35, and a second texture structure 82 on which surface irregularities are formed is formed on the first conductivity-type semiconductor layer 37.

In the photoelectric conversion substrate 20, the semiconductor layers 38 and 39 on another main surface of the semiconductor substrate 35 follow and reflect irregularities of the first texture structure 81 of the semiconductor substrate 35, and a second texture structure 83 on which surface irregularities are formed is formed on the second conductivity-type semiconductor layer 39.

In the photoelectric conversion substrate 20, the first transparent conductive layer 25 on the first conductivity-type semiconductor layer 37 follows and reflects irregularities of the second texture structure 82 of the first conductivity-type semiconductor layer 37, and a third texture structure 84 is formed.

In the photoelectric conversion substrate 20, the second transparent conductive layer 27 on the second conductivity-type semiconductor layer 39 follows and reflects irregularities of the second texture structure 83 of the second conductivity-type semiconductor 39, and a third texture structure 85 is formed.

In the photoelectric conversion substrate 20, the transparent conductive layers 25 and 27 are not formed on the entire surfaces of the substrate main surfaces 28 and 29, the second texture structures 82 and 83 are formed on a part of the substrate main surfaces 28 and 29, respectively, and the third texture structures 84 and 85 are formed on a remaining portion of the substrate main surfaces 28 and 29, respectively, in plan view.

### First Electrode Part 21

The first electrode part 21 is formed by solidifying first conductive paste, and includes a plurality of first collector electrodes 40 (40a to 40d) as illustrated in FIGS. 2 and 3A.

As illustrated in FIGS. 3A and 4, the first collector electrode 40 constitutes a part of the first cell main surface 10, and is a conductive layer partially stacked on the first substrate main surface 28 of the photoelectric conversion substrate 20.

The first collector electrode 40 protrudes in the thickness direction by its thickness with respect to another portion of the first cell main surface 10 (the first substrate main surface 28 of the photoelectric conversion substrate 20).

The thickness of the first collector electrode 40 is not particularly limited, but is preferably 5 μm or more and 40 μm or less.

As illustrated in FIGS. 2 and 3A, the first collector electrode 40 extends in a comb shape, and includes a first busbar electrode part 50 and a plurality of first finger electrode parts 51.

The first collector electrode 40 is not particularly limited as long as the first collector electrode 40 has conductivity, and can be made from, for example, a metal material containing metal such as gold, silver, aluminum, copper, or palladium or a metal alloy of these as a main component. The first collector electrode 40 is preferably higher in conductivity than the first transparent conductive layer 25 as a base.

The first collector electrode 40 of the present embodiment is formed simultaneously with the first resin coating part 23 from the first conductive paste by a first electrode forming step described later, and contains a resin component common to the first resin coating part 23.

As illustrated in FIG. 3A, the first collector electrodes 40a to 40d are independently and individually provided, and are not directly connected to each other.

As illustrated in FIG. 2, the first busbar electrode part 50 is a connection part that extends in the lateral direction X in plan view and connects end portions of the first finger electrode parts 51.

The first busbar electrode parts 50 of the first collector electrodes 40a to 40d are arranged at intervals in the longitudinal direction Y and are parallel to each other.

The first busbar electrode parts 50 of the first collector electrodes 40a to 40d of the present embodiment are arranged side by side at equal intervals in the longitudinal direction Y.

Width of the first busbar electrode part 50 is not particularly limited, but is preferably 0.1 mm or more and 8 mm or less.

The first finger electrode part 51 is a linear electrode part extending in the longitudinal direction Y from a middle section in an extending direction (the lateral direction X) of the first busbar electrode part 50 toward the lateral side 31.

As illustrated in FIG. 2, the first finger electrode parts 51 extend in the same direction and are arranged side by side at intervals D2 in the lateral direction X, and the first finger electrode parts 51 of the present embodiment are arranged side by side at equal intervals at the intervals D2 in the lateral direction X.

Width of the first finger electrode part 51 is narrower than width of the first busbar electrode part 50, and is preferably 20 μm or more and 70 μm or less.

The interval D2 between the first finger electrode parts 51 and 51 adjacent to each other is preferably 1 mm or less from the viewpoint of covering a space between the first finger electrode parts 51 and 51 with the first resin coating part 23 by bleeding of the first conductive paste in a first electrode forming step to be described later.

### Second Electrode Part 22

The second electrode part 22 is formed by solidifying second conductive paste, and includes a plurality of second collector electrodes 60 (60a to 60d) as illustrated in FIGS. 2 and 3B.

As illustrated in FIGS. 3B and 4, the second collector electrode 60 constitutes a part of the second cell main surface 11, and is a conductive layer partially stacked on the second substrate main surface 29 of the photoelectric conversion substrate 20.

The second collector electrode 60 protrudes in the thickness direction by its thickness with respect to another portion of the second cell main surface 11 (the second substrate main surface 29 of the photoelectric conversion substrate 20).

The thickness of the second collector electrode 60 is not particularly limited, but is preferably 5 μm or more and 40 μm or less.

As illustrated in FIGS. 2 and 3B, the second collector electrode 60 extends in a comb shape, and includes a second busbar electrode part 70 and a plurality of second finger electrode parts 71.

The second collector electrode 60 is not particularly limited as long as the second collector electrode 60 has conductivity, and can be made from, for example, a metal material containing metal such as gold, silver, aluminum, copper, or palladium or a metal alloy of these as a main component. The second collector electrode 60 is preferably higher in conductivity than the second transparent conductive layer 27 as a base.

The second collector electrode 60 of the present embodiment is formed simultaneously with the second resin coating part 24 from the second conductive paste by a second electrode forming step described later, and contains a resin component common to the second resin coating part 24.

As illustrated in FIG. 3B, the second collector electrodes 60a to 60d are independently and individually provided, and are not directly connected to each other.

As illustrated in FIG. 2, the second busbar electrode part 70 is a connection part that extends in the lateral direction X in plan view and connects end portions of the second finger electrode parts 71.

The second busbar electrode parts 70 of the second collector electrodes 60a to 60d are arranged at intervals in the longitudinal direction Y and are parallel to each other.

The second busbar electrode parts 70 of the second collector electrodes 60a to 60d of the present embodiment are arranged side by side at equal intervals in the longitudinal direction Y.

Width of the second busbar electrode part 70 is not particularly limited, but is preferably 0.1 mm or more and 8 mm or less.

The second finger electrode part 71 is a linear electrode part extending in the longitudinal direction Y from a middle section in the lateral direction X of the second busbar electrode part 70 toward the lateral side 30.

As illustrated in FIG. 2, the second finger electrode parts 71 extend in the same direction and are arranged side by side at intervals D3 in the lateral direction X, and the second finger electrode parts 71 of the present embodiment are arranged side by side at equal intervals at the intervals D3 in the lateral direction X.

The interval D3 between the second finger electrode parts 71 and 71 adjacent to each other is substantially the same interval, preferably the same interval, as the interval D2 between the first finger electrode parts 51 and 51 adjacent to each other.

The expression “substantially the same interval” as used here means that a difference between the interval D2 between the first finger electrode parts 51 and the interval D3 between the second finger electrode parts 71 is 1 μm or less.

Width of the second finger electrode part 71 is narrower than width of the second busbar electrode part 70, and is preferably 20 μm or more and 70 μm or less.

The interval D3 between the second finger electrode parts 71 and 71 adjacent to each other is preferably 1 mm or less from the viewpoint of covering a space between the second finger electrode parts 71 and 71 with the second resin coating part 24 by bleeding of the second conductive paste in a second electrode forming step to be described later.

### First Resin Coating Part 23

The first resin coating part 23 is a layer that protects the first substrate main surface 28 of the photoelectric conversion substrate 20 from physical and mechanical contact of the second electrode part 22 of another one of the solar cells 2 when stacked together with the another one of the solar cells 2 in formation of the stacked structure 1.

Further, the first resin coating part 23 is also a layer that protects the photoelectric conversion substrate 20 from irradiated laser beam in a laser step to be described later and suppresses damage to the photoelectric conversion substrate 20.

The first resin coating part 23 preferably has gas barrier property, insulating property, and light transmissivity.

The first resin coating part 23 of the present embodiment is obtained by solidifying a resin component containing liquid resin of the first conductive paste used for forming the first electrode part 21, and contains a resin component common to the first electrode part 21. That is, there is a resin portion continuously connected between the first electrode part 21 and the first resin coating part 23.

As illustrated in FIG. 4, the first resin coating part 23 is provided adjacent to the first electrode part 21 and is continuous with the first electrode part 21.

The first resin coating part 23 extends from the first transparent conductive layer 25 to an exposed part from the first transparent conductive layer 25 of the first conductivity-type semiconductor layer 37, and, as illustrated in FIG. 5, follows and reflects irregularities of the second texture structure 82 of the first conductivity-type semiconductor layer 37 as a base and the third texture structure 84 of the first transparent conductive layer 25 to form an irregularity region 86.

Since the irregularity region 86 is formed of a resin component containing liquid resin having fluidity, the irregularities are leveled, and surface irregularities are smaller than irregularities of the second texture structure 82 and irregularities of the third texture structure 84.

### Second Resin Coating Part 24

The second resin coating part 24 is a layer that protects the second substrate main surface 29 of the photoelectric conversion substrate 20 from physical and mechanical contact of the first electrode part 21 of another one of the solar cells 2 when stacked together with the another one of the solar cells 2 in formation of the stacked structure 1.

The second resin coating part 24 preferably has gas barrier property, insulating property, and light transmissivity.

The second resin coating part 24 of the present embodiment is obtained by solidifying a resin component containing liquid resin of the second conductive paste used for forming the second electrode part 22, and contains a resin component common to the second electrode part 22. That is, there is a resin portion continuously connected between the second electrode part 22 and the second resin coating part 24.

As illustrated in FIG. 4, the second resin coating part 24 is provided adjacent to the second electrode part 22 and is continuous with the second electrode part 22.

The second resin coating part 24 extends from the second transparent conductive layer 27 to an exposed part from the second transparent conductive layer 27 of the second conductivity-type semiconductor 39, and, as illustrated in FIG. 5, follows and reflects irregularities of the second texture structure 83 of the second conductivity-type semiconductor layer 39 as a base and the third texture structure 85 of the second transparent conductive layer 27 to form an irregularity region 87.

Since the irregularity region 87 is formed of a resin component containing liquid resin having fluidity, the irregularities are leveled, and surface irregularities are smaller than irregularities of the second texture structure 83 and irregularities of the third texture structure 85.

### Solar Cell Module 100

As illustrated in FIGS. 6 and 7, in the solar cell module 100, a plurality of the solar cell groups 103 in which a plurality of the divided solar cells 101 are electrically connected in series directly or by the conductive adhesive 102 are sandwiched between a first sealing member 115 and a second sealing member 116, and a space between the first sealing member 115 and the second sealing member 116 is filled and sealed with a first sealing material 117 and a second sealing material 118.

Further, in the solar cell module 100, as illustrated in FIG. 6, end portions in an electricity flowing direction of the solar cell groups 103 are connected to extraction wiring lines 113 and 114 to the outside, and the solar cell groups 103 are electrically connected in parallel.

### Divided Solar Cell 101

The divided solar cells 101 are obtained by cutting and dividing the solar cells 2 along a division line L1 illustrated in FIG. 2.

As illustrated in FIG. 8, in the divided solar cells 101, the first collector electrode 40 and the first resin coating part 23 are provided on the first substrate main surface 28 of the photoelectric conversion substrate 20, and the second collector electrode 60 and the second resin coating part 24 are provided on the second substrate main surface 29.

In the divided solar cells 101, a laser cut part 120 in which a laser mark is formed and a broken apart part 121 in which a breaking apart mark is formed are formed on an end surface in a width direction which is a cut surface.

The laser cut part 120 is continuous with the broken apart part 121 and constitutes an inclined surface inclined with respect to the broken apart part 121, and a protective resin layer 122 is formed on a surface.

The photoelectric conversion substrate 20 of the divided solar cells 101 has width in the longitudinal direction Y and extends in the lateral direction X in plan view.

The protective resin layer 122 is continuous with the first resin coating part 23 and contains an oxide component of a resin component contained in the first resin coating part 23.

### Conductive Adhesive 102

The conductive adhesive 102 is a conductive member having conductivity, and is an adhesive that connects the busbar electrode parts 50 and 70 of the divided solar cells 101 and 101 as illustrated in FIG. 7.

The conductive adhesive 102 of the present embodiment is a conductive adhesive film in which a conductive adhesive material is provided on both surfaces of the conductive adhesive film.

### Sealing Members 115 and 116

The sealing members 115 and 116 are insulating sealing substrates that spread in a planar shape and have sealing property and insulating property.

At least the sealing member 115 on the light receiving side is a light-pervious member capable of transmitting light in a thickness direction.

### Sealing Materials 117 and 118

The sealing materials 117 and 118 are members that have sealing property and seal the solar cell group 103 together with the sealing members 115 and 116, and are also adhesives that adhere the sealing members 115 and 116.

Next, a positional relationship of each portion of the solar cell 2 of the present embodiment will be described.

In the solar cell 2, as illustrated in FIG. 2, in plan view of the photoelectric conversion substrate 20, the second collector electrode 60 is located between the first collector electrodes 40 and 40 adjacent in the longitudinal direction Y, and the first collector electrode 40 is located between the second collector electrodes 60 and 60 adjacent in the longitudinal direction Y.

The first busbar electrode part 50 of the first collector electrodes 40a to 40c extends in parallel at a position close to the second busbar electrode part 70 of the second collector electrodes 60b to 60d that is adjacent.

A cutting region for dividing the divided solar cells 101 is provided between the first busbar electrode part 50 and the second busbar electrode part 70 closest to each other in the longitudinal direction Y.

An interval D1 (width of a cutting region) between the first busbar electrode part 50 and the second busbar electrode part 70 adjacent to each other with the division line L1 illustrated in FIG. 2 interposed between them is preferably 0.5 mm or more and 4 mm or less from the viewpoint of ease of division of the solar cell 2.

As illustrated in FIG. 4A, the first busbar electrode part 50 of each of the first collector electrodes 40 is shifted in the longitudinal direction Y and does not overlap in the thickness direction with respect to the second busbar electrode part 70 of each of the second collector electrodes 60.

As illustrated in FIG. 2, the first finger electrode part 51 of the first collector electrode 40 extends in a direction opposite to the second finger electrode part 71 of the second collector electrode 60 in plan view of the photoelectric conversion substrate 20, and a distal end in the extending direction reaches the vicinity of the facing second collector electrode 60.

The first finger electrode part 51 is located and extends between the second finger electrode parts 71 and 71 adjacent in the lateral direction X from the first busbar electrode part 50, and the second finger electrode part 71 is located and extends between the first finger electrode parts 51 and 51 adjacent in the lateral direction X from the second busbar electrode part 70.

As illustrated in FIG. 4B, the first finger electrode part 51 of each of the first collector electrodes 40 is shifted in the lateral direction X with respect to the second finger electrode part 71 of each of the second collector electrodes 60 and does not overlap the second finger electrode part 71 in the thickness direction.

Each of the first finger electrode parts 51 is located between the second finger electrode parts 71 and 71 adjacent in the lateral direction X, and is preferably located at the center between the second finger electrode parts 71 and 71 adjacent to each other.

Each of the second finger electrode parts 71 is located between the first finger electrode parts 51 and 51 adjacent in the lateral direction X, and is preferably located at the center between the first finger electrode parts 51 and 51 adjacent to each other.

As illustrated in FIG. 5, on the first cell main surface 10 of the solar cell 2, a first inner edge region 130 including the first electrode part 21 and the first resin coating part 23 is formed, and an edge of the first inner edge region 130 is formed in a range within 0.5 mm from an outer peripheral edge of the solar cell 2.

In the first inner edge region 130, a total area of the first resin coating part 23 is preferably larger than a total area of the first electrode part 21.

In the first inner edge region 130 of the first cell main surface 10, a space between the first busbar electrode parts 50 and 50 adjacent to each other is formed of the first resin coating part 23, and a space between the first finger electrode parts 51 and 51 adjacent to each other is also formed of the first resin coating part 23.

An area of the first inner edge region 130 is larger than an area of the first transparent conductive layer 25, and the first resin coating part 23 covers an end surface of the first transparent conductive layer 25 as illustrated in FIG. 5A.

Similarly, on the second cell main surface 11 of the solar cell 2, the second inner edge region 131 constituted by the second electrode part 22 and the second resin coating part 24 is formed, and an edge of the second inner edge region 131 is formed in a range within 0.5 mm from an outer peripheral edge of the solar cell 2.

In the second inner edge region 131, a total area of the second resin coating part 24 is preferably larger than a total area of the second electrode part 22.

In the second inner edge region 131 of the second cell main surface 11, a space between the second busbar electrode parts 70 and 70 adjacent to each other is formed of the second resin coating part 24, and a space between the second finger electrode parts 71 and 71 adjacent to each other is also formed of the second resin coating part 24.

An area of the second inner edge region 131 is larger than an area of the second transparent conductive layer 27, and the second resin coating part 24 covers an end surface of the second transparent conductive layer 27 as illustrated in FIG. 5A.

Next, a method for manufacturing the solar cell module 100 of the present embodiment will be described.

The method for manufacturing the solar cell module 100 is manufactured across a first manufacturing line and a second manufacturing line, and includes a solar cell manufacturing step, a stacked structure forming step, a conveying step, and a solar cell processing step.

### Solar Cell Manufacturing Step

The solar cell manufacturing step is a step of forming the solar cell 2 on the first manufacturing line.

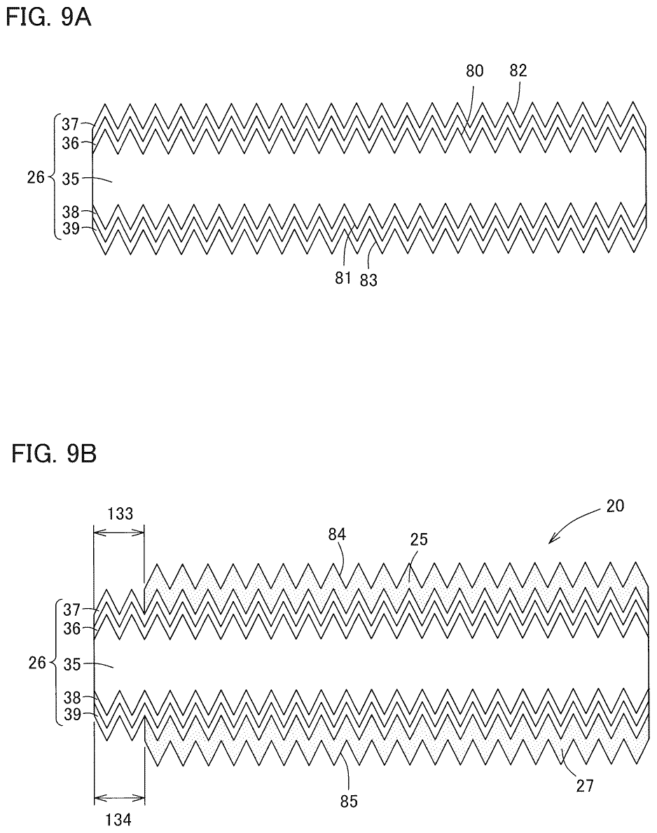

In the solar cell manufacturing step, first, both surfaces of the semiconductor substrate 35 are etched by anisotropic alkaline wet etching, and the first texture structures 80 and 81 are formed on the surface. Subsequently, the first intrinsic semiconductor layer 36 and the first conductivity-type semiconductor layer 37 are laminated in this order on one main surface of the semiconductor substrate 35 as illustrated in FIG. 9A by a plasma CVD apparatus or the like, and the second intrinsic semiconductor layer 38 and the second conductivity-type semiconductor layer 39 are laminated in this order on another main surface of the semiconductor substrate 35 to form the photoelectric conversion part 26 (photoelectric conversion part forming step).

Subsequently, as illustrated in FIG. 9B, the transparent conductive layers 25 and 27 are formed on one main surface side and another main surface side of the photoelectric conversion part 26 by a sputtering apparatus or the like to form the photoelectric conversion substrate 20 (transparent conductive layer forming step).

At this time, in the photoelectric conversion substrate 20, the transparent conductive layers 25 and 27 are formed on most of the substrate main surfaces 28 and 29 in plan view, and transparent conductive layer non-formed regions 133 and 134 in which the transparent conductive layers 25 and 27 are not formed is formed along an outer peripheral edge on the substrate main surfaces 28 and 29.

That is, the transparent conductive layer non-formed regions 133 and 134 are exposed parts of the photoelectric conversion part 26 from the transparent conductive layers 25 and 27 provided on an outer peripheral edge of the photoelectric conversion substrate 20 in plan view.

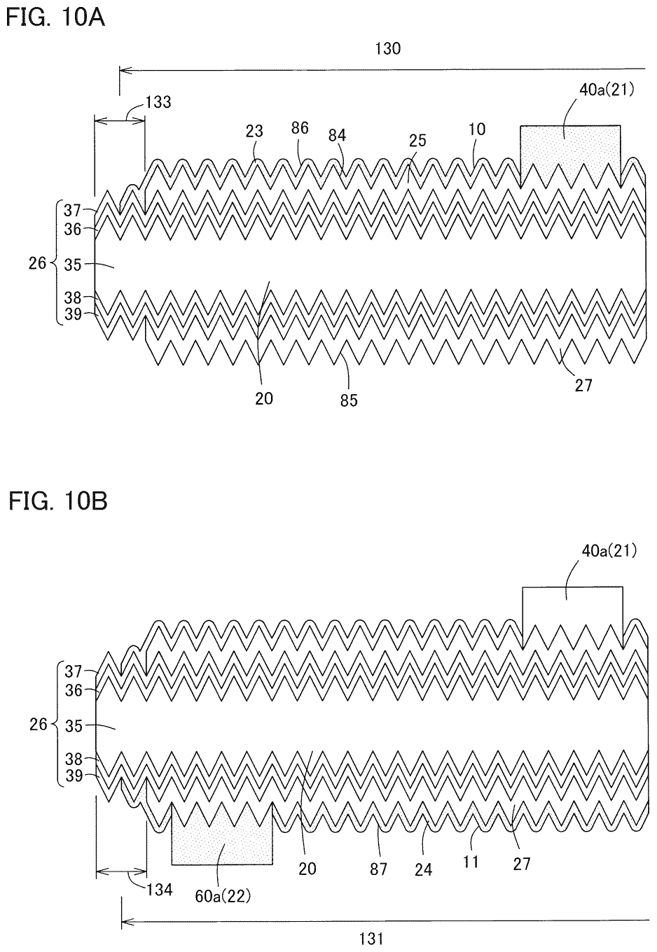

Subsequently, as illustrated in FIG. 10A, when the first conductive paste containing conductive particles and liquid resin is applied onto the first transparent conductive layer 25 constituting the first substrate main surface 28 of the photoelectric conversion substrate 20 by a screen printing method or the like, the conductive particles have high density and thus remain at a planned formation position of the first electrode part 21, while the liquid resin further oozes out from the planned formation position of the first electrode part 21.

That is, while the conductive particles aggregate at the planned formation position of the first electrode part 21 and the liquid resin is contained in a gap portion of the conductive particles, the liquid resin oozes out in the vicinity of the planned formation position of the first electrode part 21.

Then, in a state where the liquid resin of the second conductive paste oozes out from the planned formation position of the first electrode part 21 (applied area to the photoelectric conversion substrate 20), the first conductive paste is solidified by heating or the like to form the first electrode part 21 and the first resin coating part 23 (first electrode forming step).

That is, in the first electrode forming step, a liquid component containing the liquid resin oozes out into a gap of the first electrode part 21 from an applied area of the first conductive paste on which the first electrode part 21 is formed to form the first resin coating part 23.

The first electrode part 21 and the first resin coating part 23 formed in the first electrode forming step contain a common resin component. That is, there is a resin portion continuously connected between the first electrode part 21 and the first resin coating part 23. More specifically, a resin portion continuously connected is formed between a part of resin in a gap portion of the conductive particles constituting the first electrode part 21 and the first resin coating part 23.

The conductive particles used in the first conductive paste are not particularly limited as long as the conductive particles are particles having conductivity. As the conductive particles, for example, metal materials such as silver, aluminum, copper, indium, bismuth, and gallium can be used.

The liquid resin used in the first conductive paste is not particularly limited as long as the liquid resin is binder resin having liquid property and solidified by heat, an ultraviolet ray, or the like. As the liquid resin, for example, thermosetting resin such as epoxy resin, phenol resin, or acrylic resin can be used.

The first conductive paste may further contain liquid solvents such as an organic solvent or an inorganic solvent.

The first conductive paste of the present embodiment is a mixture containing conductive particles, liquid resin, and a liquid solvent.

In the first electrode forming step, as illustrated in FIG. 10A, the first inner edge region 130 is formed, the first inner edge region 130 overlaps the first transparent conductive layer non-formed region 133, the first electrode part 21 and the first resin coating part 23 cover the entire first transparent conductive layer 25, and the first resin coating part 23 reaches the first transparent conductive layer non-formed region 133 from the first transparent conductive layer 25.

That is, the first resin coating part 23 is provided so as to extend from the first transparent conductive layer 25 to an exposed part of the photoelectric conversion part 26, and an outer peripheral edge of the first inner edge region 130 is formed outside an outer peripheral edge of the first transparent conductive layer 25 and inside an outer peripheral edge of the photoelectric conversion substrate 20.

Subsequently, as illustrated in FIG. 10B, when the second conductive paste containing conductive particles and liquid resin is applied onto the second transparent conductive layer 27 constituting the second substrate main surface 29 of the photoelectric conversion substrate 20 by a screen printing method or the like, the conductive particles have high density and thus remain at a planned formation position of the second electrode part 22, while the liquid resin further oozes out from the planned formation position of the second electrode part 22.

That is, while the conductive particles aggregate at the planned formation position of the second electrode part 22 and the liquid resin is contained in a gap portion of the conductive particles, the liquid resin oozes out in the vicinity of the planned formation position of the second electrode part 22.

Then, in a state where the liquid resin of the second conductive paste oozes out from the planned formation position of the second electrode part 22 (applied area to the photoelectric conversion substrate 20), the second conductive paste is solidified by heating or the like to form the second electrode part 22 and the second resin coating part 24 (second electrode forming step).

That is, in the second electrode forming step, a liquid component containing the liquid resin oozes out into a gap of the second electrode part 21 from an applied area of the second conductive paste on which the second electrode part 22 is formed to form the second resin coating part 24.

The second electrode part 22 and the second resin coating part 24 formed in the second electrode forming step contain a common resin component. That is, there is a resin portion continuously connected between the second electrode part 22 and the second resin coating part 24. More specifically, a resin portion continuously connected is formed between a part of resin in a gap portion of the conductive particles constituting the second electrode part 22 and the second resin coating part 24.

As the second conductive paste, the same conductive particles and liquid resin as those of the first conductive paste used in the first electrode forming step can be used.

The second conductive paste of the present embodiment is a mixture containing conductive particles, liquid resin, and a liquid solvent.

In the second electrode forming step, as illustrated in FIG. 10B, the second inner edge region 131 is formed, the second inner edge region 131 overlaps the second transparent conductive layer non-formed region 134, the second electrode part 22 and the second resin coating part 24 cover the entire second transparent conductive layer 27, and the second resin coating part 24 reaches the second transparent conductive layer non-formed region 134 from the second transparent conductive layer 27.

That is, the second resin coating part 24 is provided so as to extend from the second transparent conductive layer 27 to an exposed part of the photoelectric conversion part 26, and an outer peripheral edge of the second inner edge region 131 is formed outside an outer peripheral edge of the second transparent conductive layer 27 and inside an outer peripheral edge of the photoelectric conversion substrate 20.

When the first electrode forming step and the second electrode forming step are completed, the solar cell 2 is completed, and the solar cell manufacturing step is completed.

### Stacked Structure Forming Step

The stacked structure forming step is a step of forming the stacked structure 1 in order to convey the solar cell 2 from the first manufacturing line to the second manufacturing line in the conveying step.

In the stacked structure forming step, first, as illustrated in FIG. 1, a plurality of the solar cells 2 are placed in the vertical direction Z, and the solar cells 2 are stacked in the thickness direction to form the stacked structure 1.

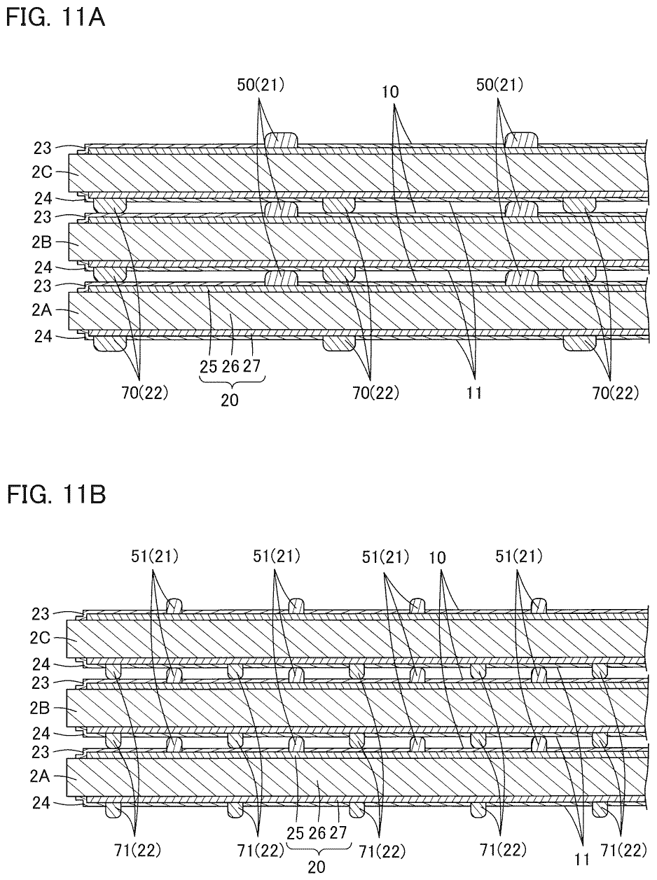

At this time, when focus is placed on solar cells 2A to 2C of three stages stacked in the thickness direction illustrated in FIG. 11, in each of the solar cells 2A to 2C, the first cell main surface 10 constitutes an upper surface, and the second cell main surface 11 constitutes a lower surface.

As illustrated in FIG. 11, in the solar cell 2B (first solar cell) of a middle stage, the second electrode part 22 of the second cell main surface 11 is in contact with and supported by the first resin coating part 23 of the first cell main surface 10 of the solar cell 2A of a lower stage, and the first electrode part 21 of the first cell main surface 10 is in contact with and supporting the second resin coating part 24 of the second cell main surface 11 of the solar cell 2C (second solar cell) of an upper stage.

In the solar cell 2B of the middle stage, the second resin coating part 24 of the second cell main surface 11 is in contact with and supported by the first electrode part 21 of the solar cell 2A of the lower stage, and the first resin coating part 23 of the first cell main surface 10 is in contact with and supporting the second electrode part 22 of the solar cell 2C of the upper stage.

### Conveying Step

The conveying step is a step of transporting the stacked structure 1 formed in the stacked structure forming step from the first manufacturing line to the second manufacturing line.

### Solar Cell Processing Step

The solar cell processing step is a step of processing a solar cell in the second manufacturing line to form the solar cell module 100.

In the solar cell processing step, first, the solar cell 2 is taken out from the stacked structure 1 formed in the stacked structure forming step, cut along the division line L1 illustrated in FIG. 2, and divided into a plurality of the divided solar cells 101 (dividing step).

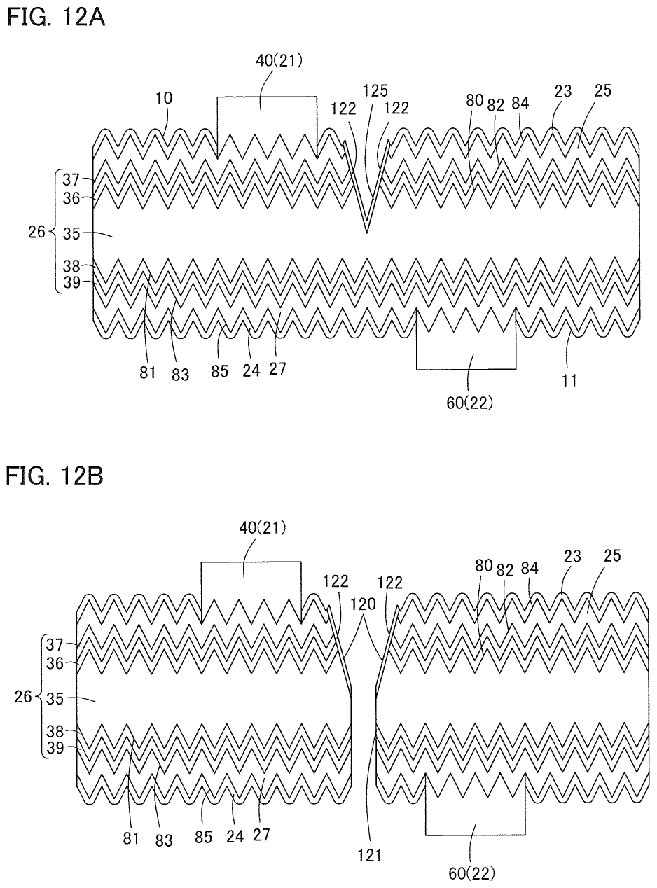

Specifically, as illustrated in FIG. 12A, a dividing groove 125 extending from the first resin coating part 23 to at least the inside of the semiconductor substrate 35 (middle section in the thickness direction) is formed by irradiating with laser beam from the first cell main surface 10 side of the solar cell 2 in a manner passing through a position overlapping the resin coating parts 23 and 24 while avoiding the electrode parts 21 and 22 in plan view (dividing groove forming step).

At this time, a part of the first resin coating part 23 is oxidized by laser beam, and the protective resin layer 122 is formed on a surface of the dividing groove 125.

Subsequently, as illustrated in FIG. 12B, the solar cell 2 is broken apart in a manner passing through the second resin coating part 24 along the dividing groove 125, and divided into a plurality of the divided solar cells 101 (breaking apart step).

At this time, the laser cut part 120 and the broken apart part 121 are formed by cutting in the thickness direction from a bottom of the dividing groove 125.

Subsequently, as illustrated in FIG. 7, the first busbar electrode part 50 and the second busbar electrode part 70 of each of the divided solar cells 101 are bonded by the conductive adhesive 102 to form the solar cell group 103 in which the divided solar cells 101 are electrically connected in series (solar cell group forming step).

Subsequently, as illustrated in FIG. 6, the busbar electrode parts 50 and 70 in end portions in an electricity flow direction of each of the solar cell groups 103 are connected to the extraction wiring lines 113 and 114, respectively (wiring line connecting step).

Subsequently, as illustrated in FIG. 7, each of the solar cell groups 103 is sandwiched between the sealing members 115 and 116, and a space between each of the solar cell groups 103 and the sealing members 115 and 116 is filled with the sealing materials 117 and 118 and sealed, so that the solar cell module 100 is completed (assembling step).

According to the solar cell 2 of the present embodiment, when the second cell main surface 11 of the solar cell 2 of the upper stage is stacked on the first cell main surface 10, most of the second electrode part 22 of the solar cell 2 of the upper stage can be received by the first resin coating part 23, so that damage such as a scratch due to contact of the second electrode part 22 of the solar cell 2 of the upper stage with the first substrate main surface 28 of the photoelectric conversion substrate 20 can be reduced.

Further, according to the solar cell 2 of the present embodiment, when the second cell main surface 11 is stacked on the first cell main surface 10 of the solar cell 2 of the lower stage, most of the first electrode part 21 of the solar cell 2 of the lower stage can be received by the second resin coating part 24, so that damage such as a scratch due to contact of the first electrode part 21 of the solar cell 2 of the lower stage with the second substrate main surface 29 of the photoelectric conversion substrate 20 can be reduced.

According to the solar cell 2 of the present embodiment, since the first electrode part 21 is adjacent to the first resin coating part 23 and contains a resin component common to the first resin coating part 23, the first electrode part 21 can be simultaneously formed of the first conductive paste. Similarly, since the second electrode part 22 is adjacent to the second resin coating part 24 and contains a resin component common to the second resin coating part 24, the second electrode part 22 can be simultaneously formed of the second conductive paste.

According to the solar cell 2 of the present embodiment, since the first finger electrode part 51, which is thinner than the first busbar electrode part 50 and is easily cut by load, overlaps the second resin coating part 24 in plan view, when the second cell main surface 11 of the solar cell 2 of the upper stage is stacked on the first cell main surface 10, the first finger electrode part 51 comes into contact with the second resin coating part 24 of the solar cell 2 of the upper stage, and the second resin coating part 24 functions as a buffer member. For this reason, the first finger electrode part 51 is hardly cut.

Further, according to the solar cell 2 of the present embodiment, since the second finger electrode part 71 that is thinner than the second busbar electrode part 70 and is easily cut by load overlaps the first resin coating part 23 in plan view, when the second cell main surface 11 of the solar cell 2 of the upper stage is stacked on the first cell main surface 10 of the solar cell 2 of the lower stage, the second finger electrode part 71 comes into contact with the first resin coating part 23 of the solar cell 2 of the lower stage, and the first resin coating part 23 functions as a buffer member. For this reason, the second finger electrode part 71 is hardly cut.

According to the method for manufacturing the solar cell 2 of the present embodiment, the first electrode part 21 and the first resin coating part 23 can be simultaneously formed of the first conductive paste, and can be easily manufactured. Similarly, the second electrode part 22 and the second resin coating part 24 can be simultaneously formed of the second conductive paste, and can be easily manufactured.

According to the solar cell 2 of the present embodiment, since the first inner edge region 130 formed in a range within 0.5 mm from an outer peripheral edge on the first cell main surface 10 is constituted by the first electrode part 21 and the first resin coating part 23, entry of moisture and the like in the thickness direction from the first cell main surface 10 can be suppressed.

Further, according to the solar cell 2 of the present embodiment, since the second inner edge region 131 formed in a range within 0.5 mm from an outer peripheral edge on the second cell main surface 11 is constituted by the second electrode part 22 and the second resin coating part 24, entry of moisture and the like in the thickness direction from the second cell main surface 11 can be suppressed.

The solar cell 2 of the present embodiment includes a resin portion in which the electrode parts 21 and 22 and the resin coating parts 23 and 24 are continuously connected, so that moisture and the like can be prevented from entering through a gap between the electrode parts 21 and 22 and the resin coating parts 23 and 24.

According to the solar cell 2 of the present embodiment, since a total area of the resin coating parts 23 and 24 is larger than a total area of the electrode parts 21 and 22 in the inner edge regions 130 and 131, it is possible to ensure a large light receiving area while preventing entry of moisture and the like.

According to the solar cell 2 of the present embodiment, in the first inner edge region 130, a space between the first finger electrode parts 51 and 51 adjacent to each other is formed of the first resin coating part 23, so that entry of moisture and the like can be further prevented.

Further, according to the solar cell 2 of the present embodiment, in the second inner edge region 131, a space between the second finger electrode parts 71 and 71 adjacent to each other is formed of the second resin coating part 24, so that entry of moisture and the like can be further prevented.

According to the solar cell 2 of the present embodiment, the resin coating parts 23 and 24 include the irregularity regions 86 and 87 having irregularities smaller than irregularities of the second texture structures 82 and 83 and irregularities of the third texture structures 84 and 85. Therefore, wettability in the vicinity of the electrode parts 21 and 22 can be reduced, and wet spread of the conductive adhesive 102 can be prevented even in a case where the conductive adhesive 102 protrudes from the electrode parts 21 and 22 in the solar cell group forming step.

According to the solar cell 2 of the present embodiment, since a PN junction portion is protected by the first electrode part 21 and the first resin coating part 23, the PN junction portion is hardly affected by entry of moisture or mechanical contact.

According to the solar cell 2 of the present embodiment, since the inner edge regions 130 and 131 includes the electrode parts 21 and 22 and the resin coating parts 23 and 24, entry of moisture and the like into the photoelectric conversion part 26 can be suppressed even if the transparent conductive layers 25 and 27 are interposed between the inner edge regions 130 and 131 and the photoelectric conversion part 26.

According to the solar cell 2 of the present embodiment, the resin coating parts 23 and 24 coat the transparent conductive layers 25 and 27 along outer peripheries of the transparent conductive layers 25 and 27, and reach the transparent conductive layer non-formed regions 133 and 134 from the transparent conductive layers 25 and 27. That is, since the resin coating parts 23 and 24 cover end surfaces of the transparent conductive layers 25 and 27, entry of moisture and the like in an interface direction between the photoelectric conversion part 26 and the transparent conductive layers 25 and 27 can be suppressed.

According to the method for manufacturing the divided solar cells 101 of the present embodiment, since a portion where the dividing groove 125 is formed of the photoelectric conversion substrate 20 is protected by the first resin coating part 23, it is possible to suppress influence on the photoelectric conversion substrate 20 when the dividing groove 125 is formed.

According to the method for manufacturing the divided solar cell 101 of the present embodiment, since a portion to be broken apart of the photoelectric conversion substrate 20 is protected by the second resin coating part 24, it is possible to suppress influence on the photoelectric conversion substrate 20 at the time of breaking apart.

According to the divided solar cell 101 of the present embodiment, since the protective resin layer 122 is formed on a part of an end surface of the photoelectric conversion substrate 20, a short circuit is less likely to occur at the end surface of the photoelectric conversion substrate 20, and reliability is high.

According to the solar cell 2 of the present embodiment, since the first electrode part 21 and the second electrode part 22 do not overlap each other in plan view, it is possible to prevent defects such as chipping and cracking due to contact between the electrode parts 21 and 22 when the solar cell 2 is stacked together with another one of the solar cells 2.

According to the solar cell 2 of the present embodiment, the first finger electrode part 51 and the second finger electrode part 71 extend in opposite directions between the first busbar electrode part 50 and the second busbar electrode part 70 in plan view, and thus, in a case where a plurality of the solar cells 2 are stacked, load is uniformly applied in a plane of the solar cell 2, and stability is improved.

According to the solar cell 2 of the present embodiment, in plan view, the first finger electrode part 51 is located and extend between the second finger electrode parts 71 and 71 adjacent in the lateral direction X, and the second finger electrode part 71 is located and extend between the first finger electrode parts 51 and 51 adjacent in the lateral direction X. For this reason, in a case where a plurality of the solar cells 2 are stacked, load is uniformly applied in a plane of the solar cells 2, so that stability is improved.

According to the solar cell 2 of the present embodiment, the second collector electrode 60b is located between the first collector electrodes 40a and 40b independent of each other, and the first collector electrode 40a is located between the second collector electrodes 60a and 60b independent of each other. For this reason, even if cutting is performed between the first collector electrode 40a and the second collector electrode 60b, each of the divided solar cells 101 obtained by cutting can extract power from the first collector electrode 40a (40b) and the second collector electrode 60a (60b).

According to the stacked structure 1 of the present embodiment, since the first electrode part 21 of the solar cell 2B in the lower stage and the second electrode part 22 of the solar cell 2C in the upper stage are not in contact with each other, it is possible to prevent defects such as chipping and cracking due to contact between the electrode parts 21 and 22.

In the above embodiment, the solar cells 2 are stacked in the vertical direction Z while the solar cells 2 are laid, but the present invention is not limited to this. The solar cells 2 may be stacked in a direction intersecting the vertical direction Z while the solar cells 2 is stood upright.

In the above embodiment, a plurality of the solar cells 2 are stacked, but the present invention is not limited to this. A plurality of the divided solar cells 101 may be stacked.

In the above embodiment, one of the solar cells 2 is divided into four of the divided solar cells 101, but the present invention is not limited to this. One of the solar cells 2 may be divided into two or more and three or less of the divided solar cells 101, or may be divided into five or more of the divided solar cells 101. In this case, the number of the collector electrodes 40 and 60 is increased or decreased according to the number of the divided solar cells 101 obtained by dividing.

In the above embodiment, the solar cell 2 is divided into a plurality of the divided solar cells 101, but the present invention is not limited to this. The solar cell 2 does not need to be divided.

In the embodiment described above, the second electrode forming step is performed after the first electrode forming step, but the present invention is not limited to this. The first electrode forming step may be performed after the second electrode forming step.

In the above embodiment, a PN junction portion is provided on the first cell main surface 10 side with respect to the semiconductor substrate 35, but the present invention is not limited to this. The PN junction portion may be provided on the second cell main surface 11 side with respect to the semiconductor substrate 35.

In the above-described embodiment, the electrode parts 21 and 22 include the busbar electrode parts 50 and 70 and the finger electrode parts 51 and 71, but the present invention is not limited to this. The solar cell may be what is called a busbar-less solar cell in which no busbar electrode is provided.

In the above embodiment, the first finger electrode parts 51 are arranged side by side at equal intervals, but the present invention is not limited to this. The first finger electrode parts 51 may be arranged at non-equal intervals. Similarly, in the above-described embodiment, the second finger electrode parts 71 are arranged side by side at equal intervals, but the present invention is not limited to this. The second finger electrode parts 71 may be arranged at non-equal intervals.

In the above-described embodiment, the interval D2 between the first finger electrode parts 51 and the interval D3 between the second finger electrode parts 71 are substantially the same, but the present invention is not limited to this. The interval D2 between the first finger electrode parts 51 may be narrower than the interval D3 between the second finger electrode parts 71, and the interval D3 between the second finger electrode parts 71 may be narrower than the interval D2 between the first finger electrode parts 51.

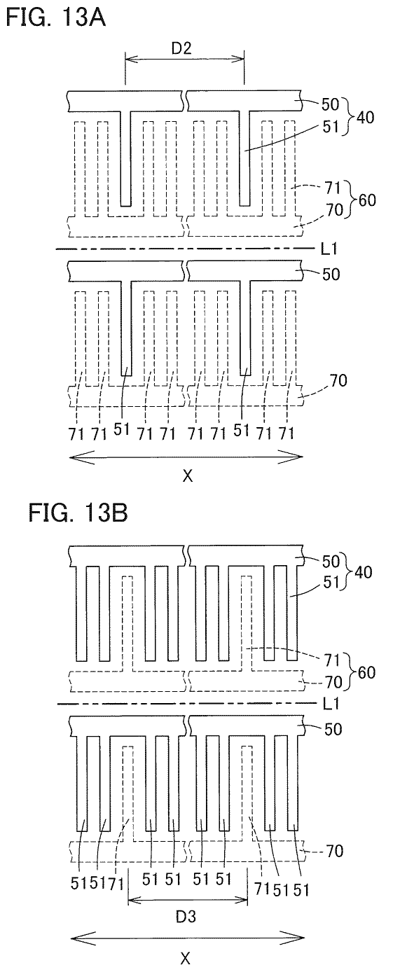

Further, as illustrated in FIG. 13A, a plurality of the first finger electrode parts 51 may be located between the second finger electrode parts 71 and 71 adjacent in the lateral direction X. Further, as illustrated in FIG. 13B, a plurality of the second finger electrode parts 71 may be located between the first finger electrode parts 51 and 51 adjacent in the lateral direction X.

For example, as illustrated in FIG. 13A, in a case where a plurality of the first finger electrode parts 51 are arranged side by side at the intervals D2 at equal intervals, and a plurality of the second finger electrode parts 71 are arranged side by side at intervals D2/n (n is a natural number of 2 or more) at equal intervals, the configuration may be such that each of the first finger electrode parts 51 is located at the center of the second finger electrode parts 71 and 71 adjacent in the lateral direction X, and n of the second finger electrode parts 71 are located between the first finger electrode parts 51 and 51 adjacent to each other.

Further, for example, as illustrated in FIG. 13B, in a case where a plurality of the second finger electrode parts 71 are arranged side by side at the intervals D3, and a plurality of the first finger electrode parts 51 are arranged side by side at intervals D3/n (n is a natural number of 2 or more), the configuration may be such that each of the second finger electrode parts 71 is located at the center of the first finger electrode parts 51 and 51 adjacent in the lateral direction X, and n of the first finger electrode parts 51 are located between the second finger electrode parts 71 and 71 adjacent to each other.

In the above embodiment, in the solar cell 2, the electrode parts 21 and 22 are arranged at intervals in the longitudinal direction Y, but the present invention is not limited to this. In the solar cell 2, the electrode parts 21 and 22 may be arranged in the lateral direction X.

In the above embodiment, the case where the solar cell 2 is a crystalline solar cell and is a heterojunction solar cell is described, but the present invention is not limited to this. The solar cell 2 may be another type of solar cell. For example, the solar cell 2 may be a PERC type solar cell.

In the embodiment described above, the first inner edge region 130 is formed only of the first electrode part 21 and the first resin coating part 23, but the present invention is not limited to this. In the first inner edge region 130, the photoelectric conversion substrate 20 may be partially exposed from the first electrode part 21 and the first resin coating part 23. Similarly, the second inner edge region 131 is formed only of the second electrode part 22 and the second resin coating part 24, but the present invention is not limited to this. In the second inner edge region 131, the photoelectric conversion substrate 20 may be partially exposed from the second electrode part 22 and the second resin coating part 24.

In the above embodiment, the resin coating parts 23 and 24 are formed on both the substrate main surfaces 28 and 29 of the photoelectric conversion substrate 20, but the present invention is not limited to this. The configuration may be such that only the substrate main surface 28, one of both the substrate main surfaces 28 and 29 of the photoelectric conversion substrate 20, is coated with the resin coating part 23 (resin coating part 24).

In the above embodiment, the resin coating parts 23 and 24 are formed on both the first substrate main surface 28 side and the second substrate main surface 29 side of the photoelectric conversion substrate 20, but the present invention is not limited to this. The configuration may be such that the resin coating part 23 (resin coating part 24) is formed only on one of the main surface sides, the substrate main surface 28 (substrate main surface 29) side, of the photoelectric conversion substrate 20.

In the above embodiment, in the solar cell 2, the entire first electrode part 21 overlaps the second resin coating part 24 in plan view of the photoelectric conversion substrate 20, but the present invention is not limited to this. Most of the first electrode part 21 may overlap the second resin coating part 24, and a remaining portion may overlap the second electrode part 22.

Similarly, in the solar cell 2, the entire second electrode part 22 overlaps the first resin coating part 23 in plan view of the photoelectric conversion substrate 20, but the present invention is not limited to this. Most of the second electrode part 22 may overlap the first resin coating part 23, and a remaining portion may overlap the first electrode part 21.

In the above-described embodiment, in the stacked structure 1, both the busbar electrode parts 50 and 70 and the finger electrode parts 51 and 71 are in contact with the resin coating parts 24 and 23, but the present invention is not limited to this. The busbar electrode parts 50 and 70 do not need to be in contact with the resin coating parts 24 and 23. That is, the resin coating parts 24 and 23 do not need to be provided at positions corresponding to the busbar electrode parts 50 and 70, and the busbar electrode parts 50 and 70 may be in contact with each other. Further, a distal end of the first finger electrode part 51 of the solar cell 2B of the lower stage may be in contact with the second busbar electrode part 70 of the solar cell 2C of the upper stage.

In the above-described embodiment, thickness of the first electrode part 21 and thickness of the second electrode part 22 are substantially the same, but the present invention is not limited to this. The thickness of the first electrode part 21 may be larger than the thickness of the second electrode part 22. In this case, in the stacked structure as illustrated in FIG. 11, in the solar cell 2B of the middle stage (first solar cell), the first electrode part 21 of the first cell main surface 10 is in contact with the second resin coating part 24 of the second cell main surface 11 of the solar cell 2C of the upper stage (second solar cell) to support the solar cell 2C. Further, in the solar cell 2B of the middle stage, the second resin coating part 24 of the second cell main surface 11 is in contact with and supported by the first electrode part 21 of the solar cell 2A of the lower stage.

In the above-described embodiment, thickness of the first electrode part 21 and thickness of the second electrode part 22 are substantially the same, but the present invention is not limited to this. The thickness of the second electrode part 22 may be larger than the thickness of the first electrode part 21. In this case, in the stacked structure as illustrated in FIG. 11, in the solar cell 2B (first solar cell) of the middle stage, the second electrode part 22 of the second cell main surface 11 is in contact with and supported by the first resin coating part 23 of the first cell main surface 10 of the solar cell 2A of the lower stage. Further, in the solar cell 2B of the middle stage, the first resin coating part 23 of the first cell main surface 10 is in contact with and supporting the second electrode part 22 of the solar cell 2C of the upper stage.

In the above-described embodiment, the dividing groove 125 is formed by irradiating with laser beam, but the present invention is not limited to this. The dividing groove 125 may be formed by another method such as a dicing saw.

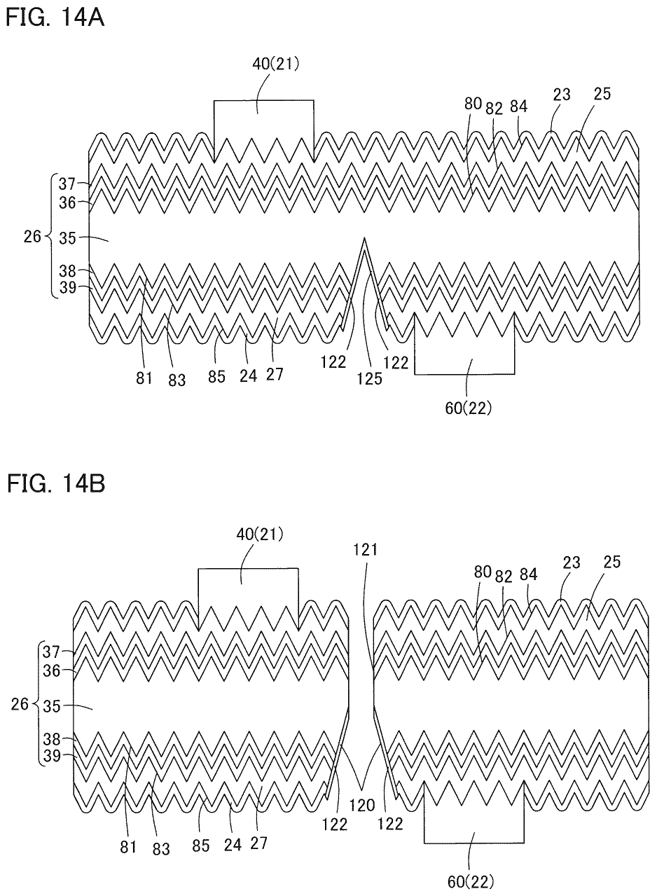

In the embodiment described above, in the dividing step, the dividing groove 125 is formed by irradiating with laser beam from the first cell main surface 10 side, and folding is performed along the dividing groove 125 so that division into a plurality of the divided solar cells 101 is performed, but the present invention is not limited to this. In the dividing step, as illustrated in FIG. 14A, the dividing groove 125 may be formed by irradiating with laser beam from the second cell main surface 11 side, and as illustrated in FIG. 14B, folding may be performed along the dividing groove 125 so that division into a plurality of the divided solar cells 101 is performed.

Further, in the dividing step, the dividing groove 125 extending over the entire solar cell 2 in the thickness direction may be formed by irradiating with laser beam so that division into a plurality of the divided solar cells 101 is performed. That is, division into a plurality of the divided solar cells 101 may be performed only by the laser step. In this case, laser beam may be irradiated from the first cell main surface 10 side, or laser beam may be irradiated from the second cell main surface 11 side. In this case, the protective resin layer 122 is formed on an entire end surface of the photoelectric conversion substrate 20.

In the embodiment described above, a space between the first collector electrodes 40 and 40 adjacent to each other is coated with the first resin coating part 23 in plan view, but the present invention is not limited to this. As long as a portion through which the division line L1 passes is coated with the resin coating parts 23 and 24, a coating range of the resin coating parts 23 and 24 is not particularly limited.

In the above-described embodiments, each component member can be freely replaced or added between the embodiments as long as they are included in the technical scope of the present invention.

### EXPLANATION OF REFERENCE SIGNS

20: photoelectric conversion substrate
21: first electrode part
22: second electrode part
23: first resin coating part
24: second resin coating part
28: first substrate main surface (first main surface)
29: second substrate main surface (second main surface)
101: divided solar cell
120: laser cut part
121: broken apart part
122: protective resin layer
125: dividing groove

1. A method for manufacturing a divided solar cell, the method comprising:
a first electrode forming step of applying conductive paste containing liquid resin onto a first main surface of a photoelectric conversion substrate and solidifying the conductive paste in a state where a part of the liquid resin of the conductive paste oozes out from an applied area on the photoelectric conversion substrate, thereby forming a first electrode part and a first resin coating part containing a resin component of the liquid resin; and
a dividing groove forming step of forming a dividing groove from a side of the first main surface of the photoelectric conversion substrate on which the first electrode part and the first resin coating part are formed in the first electrode forming step so as to pass through the first resin coating part.

2. A method for manufacturing a divided solar cell, the method comprising:
a second electrode forming step of applying conductive paste containing liquid resin onto a second main surface of a photoelectric conversion substrate, and solidifying the conductive paste in a state where a part of the liquid resin of the conductive paste oozes out from an applied area on the photoelectric conversion substrate, thereby forming a second electrode part and a second resin coating part containing a resin component of the liquid resin;
a dividing groove forming step of forming, on a photoelectric conversion substrate on which the second electrode part and the second resin coating part are formed in the second electrode forming step, a dividing groove from a first main surface side of the photoelectric conversion substrate so as to pass through a position overlapping the second resin coating part in plan view; and
a breaking apart step of breaking apart the photoelectric conversion substrate on which the dividing groove is formed along the dividing groove from the dividing groove to the second resin coating part to divide the photoelectric conversion substrate into a plurality of divided solar cells.

3. The method for manufacturing a divided solar cell according to claim 1, wherein a photoelectric conversion substrate on which the dividing groove is formed is broken apart along the dividing groove to be divided into a plurality of divided solar cells.

4. The method for manufacturing a divided solar cell according to claim 1, wherein in the dividing groove forming step, the dividing groove is formed by irradiating with laser beam.

5. A divided solar cell, comprising:
a photoelectric conversion substrate;
a first electrode part formed on the photoelectric conversion substrate; and
a resin coating part adjacent to the first electrode part,
wherein the first electrode part and the resin coating part contain a common resin component,
the photoelectric conversion substrate has a protective resin layer formed on a part or whole of an end surface, and
the protective resin layer is continuous with the resin coating part and contains the resin component or an oxide component of the resin component.

6. The method for manufacturing a divided solar cell according to claim 2, wherein in the dividing groove forming step, the dividing groove is formed by irradiating with laser beam.
